(19) United States
(12) Patent Application Publication
(10) Pub. No.: US 2004/0175934 A1
(43) Pub. Date: Sep. 9, 2004

(54) METHOD FOR IMPROVING ETCH SELECTIVITY EFFECTS IN DUAL DAMASCENE PROCESSING

(75) Inventors: William G. America, Kingston, NY (US); Parijat Bhatnagar, Ithaca, NY (US); Eugene J. O'Sullivan, Nyack, NY (US); Richard S. Wise, New Windsor, NY (US)

Correspondence Address: Sean F. Sullivan, Esq., Cantor Colburn LLP, 55 Griffin Road South, Bloomfield, CT, 06002, US

(73) Assignee: International Business Machines Corporation, Armonk, NY

(21) Appl. No.: 10/248,940

(22) Filed: Mar. 4, 2003

(51) Int. Cl. H01L 21/4763; H01L 21/44

(52) U.S. Cl. 438/638; 438/637; 438/631; 438/672

(57) ABSTRACT

A method for forming an interconnect structure in a semiconductor device includes defining a first insulator layer on a substrate and defining a via in the first insulator layer, thereby exposing a portion of the substrate. A sacrificial material is deposited over the first insulator layer and within the via, the sacrificial material being deposited at a thickness so as to also form a second insulator layer. A metallization line trench is defined in the second insulator layer, the trench being aligned over the via. Then, the sacrificial material is removed from the via opening, thereby allowing the via and the trench to be filled with a conductive material by dual damascene processing, wherein the formation of the trench and the removal of the sacrificial material from the via is implemented through a single etching operation.

### BACKGROUND OF INVENTION

The present invention relates generally to semiconductor device processing and, more particularly, to a method for improving etch selectivity effects in dual damascene processing.

Damascene processing is an interconnection fabrication technique used in the manufacture of very and ultra large scale integration (VLSI and ULSI) circuits, in which conductive lines and vias are formed within an insulating or dielectric material (e.g., silicon oxide) in order to interconnect the active and/or passive elements of the integrated circuit. Typically, the integrated circuit includes multilevel metal signal lines formed in the insulating layers of a multilayer substrate, on which individual semiconductor devices are mounted.

More specifically, trenches are formed in a dielectric layer and thereafter filled with metal to form conductive lines. Dual damascene is a multi-level interconnection process in which, in addition to forming the trenches of single damascene, the conductive via openings also are formed. Dual damascene is generally considered to be an improvement over single damascene because it permits the filling of both the conductive trenches and vias with metal at the same time, thereby eliminating process steps. In a standard dual damascene process, two photolithographic processes and two dielectric layers separated by an etch stop layer are employed to achieve the dual damascene structure.

FIGS. 1(a) through 1(j) illustrate an existing single damascene hybrid process, wherein the material used for the line (trench) level dielectric is different from the via level dielectric material. As shown in FIG. 1(a), a semiconductor substrate 100 has a via dielectric 102 deposited thereupon at thickness, for example, of about 300 nanometers (nm). The substrate 100, for purposes of illustration, is presumed to have been processed through a first metal interconnect layer. In FIG. 1(b), a via lithography step is performed, in which a photoresist layer 104 is deposited and patterned so as to define a via opening 106. In FIG. 1(c), a via 108 is thereafter created by etching the exposed portion of the via dielectric 102 as defined by via opening 106. The etch step is relatively simple to implement in this instance, given the relatively shallow depth thereof.

Then, in accordance with single damascene processing, a layer of metal (e.g., copper) 110 is deposited over the via dielectric 102 and filling the via 108, as shown in FIG. 1(d). The metal layer 110 is further planarized down to the via dielectric 102, such as by chemical mechanical polishing in FIG. 1(e). Following the completion of the via metallization, a line dielectric layer 112 is formed (e.g., at a thickness of about 300 nm) over the via dielectric layer 102 and via 108. This is illustrated in FIG. 1(f). In a manner similar to the formation of the via 108, a second photolithography step is performed (FIG. 1(g)) in which another photoresist layer 114 is deposited and patterned so as to define a line or trench opening 116. The photoresist layer 114 is patterned such that the trench opening 116 is aligned over the existing via 108. Then, as shown in FIG. 1(h), the line dielectric layer 112 is etched to create a trench 118. Because the line dielectric etch is also relatively shallow, it too is a fairly simple process. Finally, FIG. 1(i) illustrates the second metal fill step, wherein another layer of copper 120 is formed over the line dielectric layer 112 and into the trench 118. The copper layer 120 is thereafter planarized to complete the single damascene process in FIG. 1(j). It should be noted that for purposes of simplicity, FIGS. 1(a)-(j) do not illustrate any diffusion barrier layers typically associated with metallization layers.

Those skilled in the art will recognize that by implementing two separate metal fill and polish steps, the total number of processing steps is increased, thereby increasing total manufacturing costs. Thus, a less expensive alternative is a conventional dual damascene approach as illustrated in FIGS. 2(a) through 2(f).

As shown in FIG. 2(a), a substrate 200 has both a via dielectric layer 202 and a line dielectric layer 204 deposited thereupon, each at an exemplary thickness of about 300 nm. Again, the line and via dielectric materials are typically different from one another so that the via dielectric layer 202 may serve as an etch stop layer. Then, in FIG. 2(b), a first lithography step is carried out by forming a via opening 206 in photoresist layer 208. The via etch is then carried out, as shown in FIG. 2(c), to form a via 210 that initially extends through both the line dielectric layer 204 and via dielectric layer 202. In contrast to the via etch in single damascene processing, the via etch shown in FIG. 2(c) becomes more difficult, due to the increased etch depth (e.g., 600-700 nm), leading to a loss of photoresist material. Furthermore, the selection of etch chemistry must take into account the two different dielectric materials.

Once the via 210 is formed, a second lithography step is carried out, as shown in FIG. 2(d), in preparation of forming a trench over the via 210. Another layer of photoresist 212 is deposited and patterned, thereby forming a trench opening 214. This step is also more difficult as compared to single damascene processing, on account of the presence of the unfilled via 210 through the line and via dielectric layers; the photoresist topography makes pattern focusing tougher, and there is the possibility of contamination in the lower levels. Nonetheless, the line etch and formation of the trench 216 is shown in FIG. 2(e), wherein the via dielectric layer 202 is typically used as an etch stop layer. Lastly, FIG. 2(f) illustrates the deposition of the copper fill 218 and polish step that fills both the via 210 and trench 216.

Thus, it will be appreciated that there are both advantages and disadvantages to single versus dual damascene processing. On one hand, the approach in FIGS. 2(a)-(f) is less expensive than the approach outlined in FIGS. 1(a)-(h), since it avoids the extra metal fill steps, and the polish of the via metal fill down to the via dielectric. However, on the other hand, there is a tradeoff in terms of lithography and etch difficulties over the single damascene process. Accordingly, it is desirable to be able to implement a damascene technique which utilizes the advantages of both single and dual damascene processing, but avoids the disadvantages associated with each.

### SUMMARY OF INVENTION

The foregoing discussed drawbacks and deficiencies of the prior art are overcome or alleviated by a method for forming an interconnect structure in a semiconductor device. In an exemplary embodiment, the method includes defining a first insulator layer on a substrate and defining a via in the first insulator layer, thereby exposing a portion of the substrate. A sacrificial material is deposited over the first insulator layer and within the via, the sacrificial material being deposited at a thickness so as to also form a second insulator layer. A metallization line trench is defined in the second insulator layer, the trench being aligned over the via. Then, the sacrificial material is removed from the via, thereby allowing the via and the trench to be filled with a conductive material by dual damascene processing, wherein the formation of the trench and the removal of the sacrificial material from the via is implemented through a single etching operation.

In another aspect, a method for forming back end of line (BEOL) interconnect structures in a semiconductor device includes defining a via level dielectric on a lower metallization level and defining a via in the via level dielectric, thereby exposing a portion of the lower metallization level. A sacrificial material is deposited over the via level dielectric and within the via, the sacrificial material being deposited at a thickness so as to also form a trench level dielectric. An upper metallization line trench is defined in the trench level dielectric, the trench being aligned over the via. Then, the sacrificial material is removed from the via, thereby allowing the via and the trench to be filled with a conductive material by dual damascene processing, wherein the formation of the trench and the removal of the sacrificial material from the via is implemented through a single etching operation.

### BRIEF DESCRIPTION OF DRAWINGS

Referring to the exemplary drawings wherein like elements are numbered alike in the several Figures:

FIGS. 1(a) through 1(j) illustrate an existing single damascene hybrid process, wherein the material used for the line (trench) level dielectric is different from the via level dielectric material;

FIGS. 2(a) through 2(f) illustrate conventional dual damascene approach as an alternative to the single damascene process illustrated in FIGS. 1(a) through 1(j); and

FIGS. 3(a) through 3(i) illustrate processing steps of a method for forming an interconnect structure in a semiconductor device, for improving etch selectivity effects, in accordance with an embodiment of the invention.

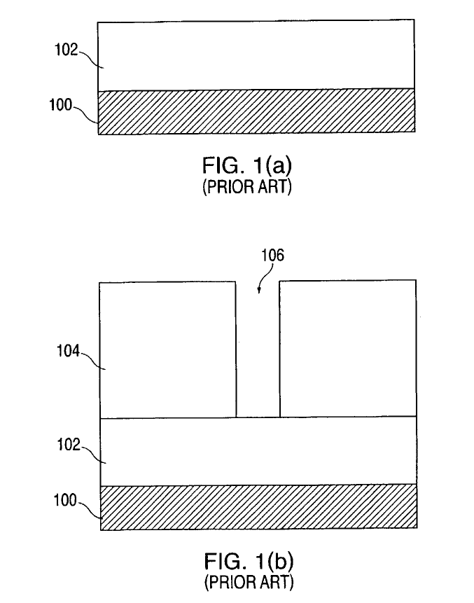

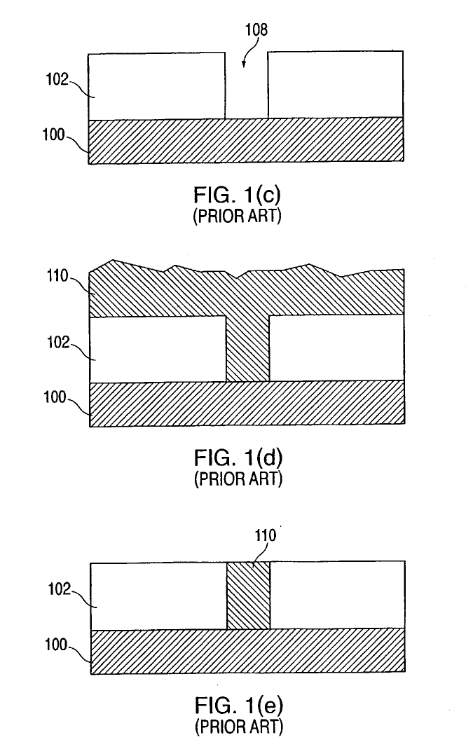

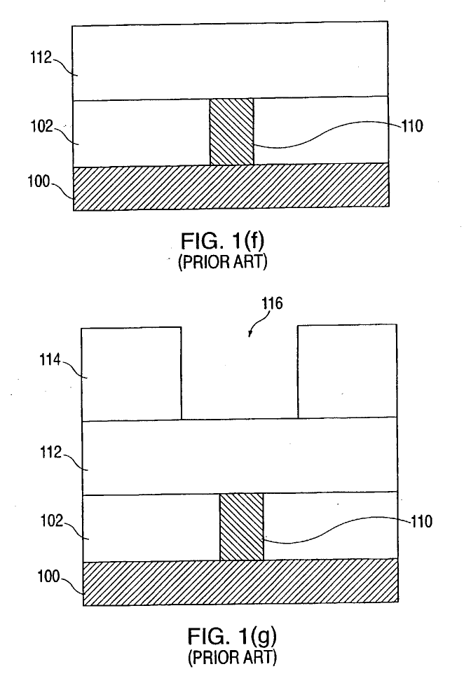

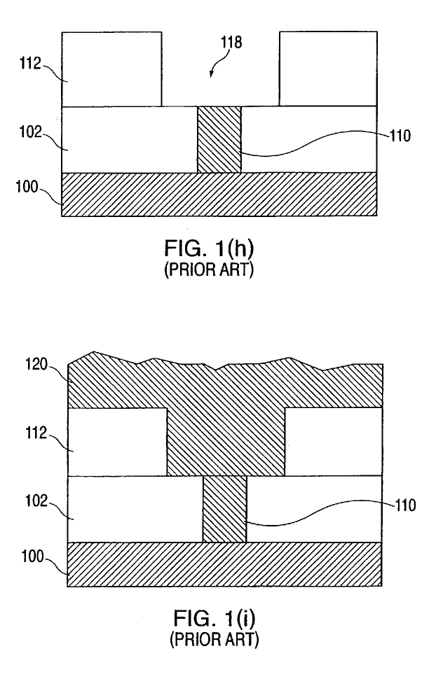

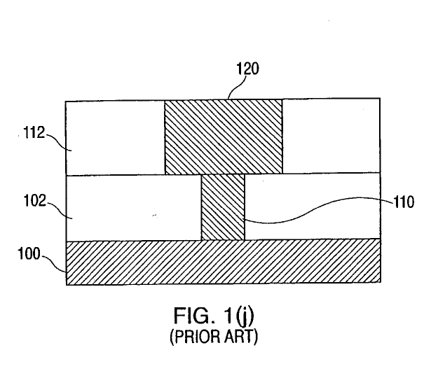

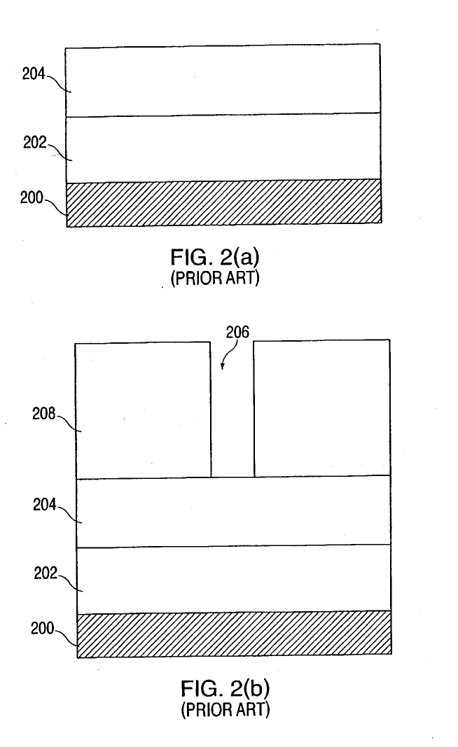

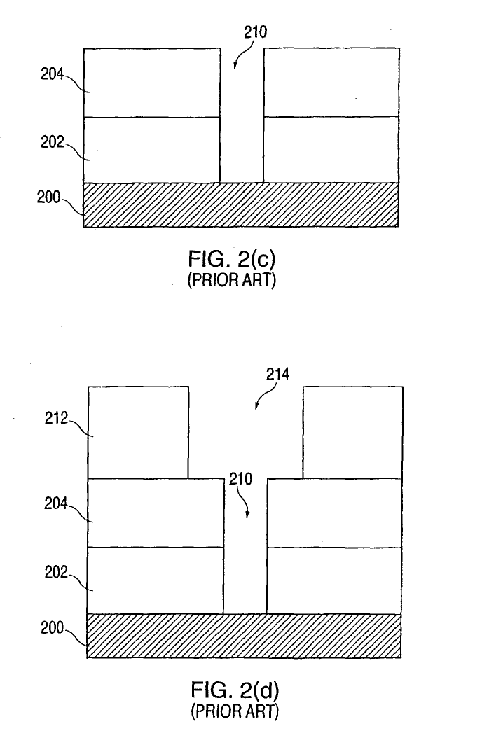

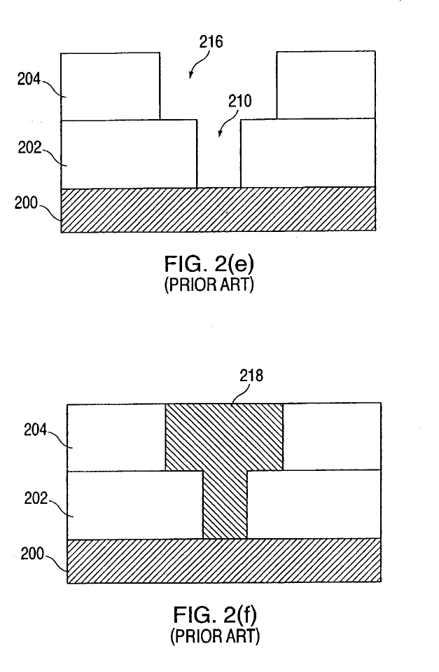

### DETAILED DESCRIPTION

Disclosed herein is a method for improving etch selectivity effects in dual damascene processing, such as implemented in the formation of back end of line (BEOL) interconnect structures. Briefly stated, the novel dual damascene process implements a via etch step and sacrificial fill thereof prior to the trench etching step. However, as opposed to previous approaches to implementing via sacrificial fills, the present invention embodiments utilize a fill material (e.g., SiLK®) that also serves as the line (trench) level dielectric, and accordingly has a substantially different etch selectivity from that of the via dielectric material. This allows for the formation of the trench structures in the line level and the removal of the via fill material in a single processing step.

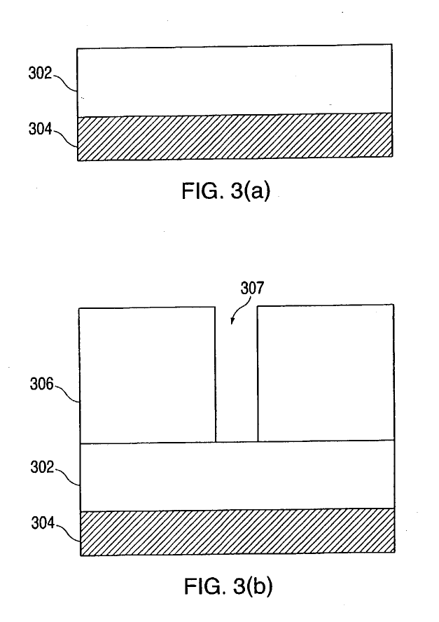

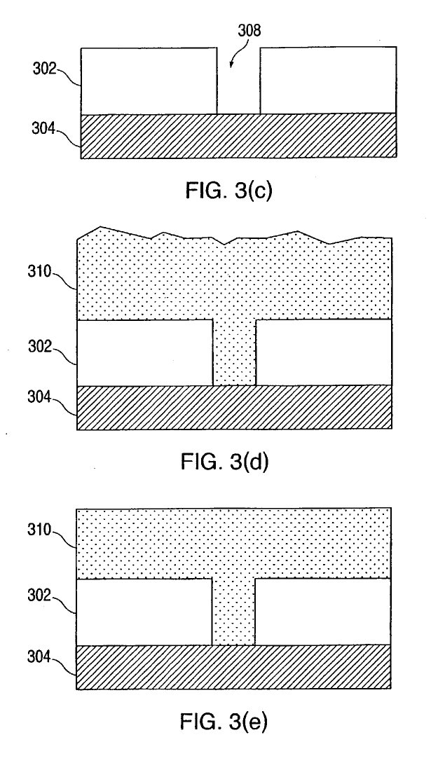

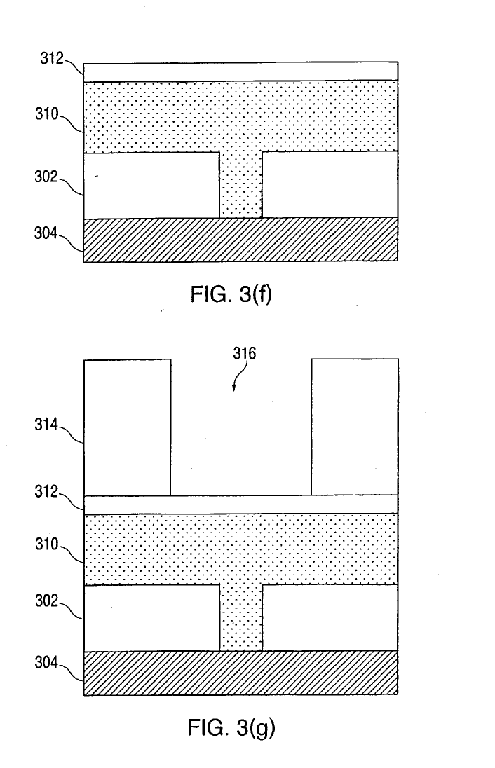

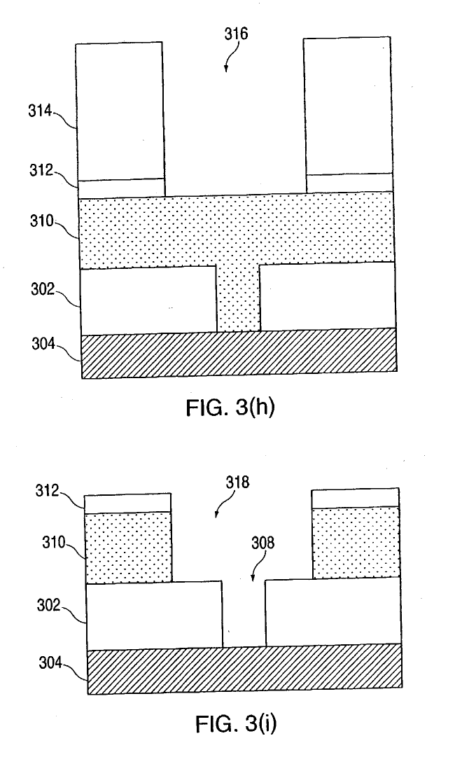

Referring generally to FIGS. 3(a) through 3(i), a method for improving etch selectivity effects, in accordance with an embodiment of the invention, is illustrated. As shown in FIG. 3(a), a via dielectric layer 302 is formed over an underlying substrate 304 (e.g., a lower metallization layer). The via dielectric layer 302 is preferably an oxide of silicon (SiOₓ), however other dielectric materials such as silicon nitride may be used. In FIG. 3(b), a layer of photoresist 306 is deposited in preparation of forming a patterned via opening 307 to be transferred within the via dielectric layer 302. The etched via 308 is shown in FIG. 3(c). Then, as shown in FIG. 3(d), a sacrificial via fill material 310 is used to fill the via 308.

The via fill material 310 is preferably an organic material, and may include a low-k dielectric material such as SiLK®, a polymer manufactured by The Dow Chemical Company. In addition to serving as a sacrificial via fill, material 310 is formed at a sufficient thickness (e.g., 300 nm) so as to also serve as a line dielectric material. Generally, if SiLK® is chosen as the via fill/line dielectric material 310, it is likely that there is sufficient planarity in the application thereof to immediately proceed to the next processing steps. Alternatively, the material 310 may be subjected to an affirmative planarizing step (such as CMP), as shown in FIG. 3(e).

Prior to the application of another layer of photoresist material for trench patterning, a hardmask layer 312 may be deposited atop material 310, as shown in FIG. 3(f). The hardmask layer 312 may include an oxide of silicon (SiOₓ), as well as a silicon carbide layer (e.g., an amorphous hydrogenated silicon carbide material, SiₓC_{y}H_{z}, such as Blok_{®} available from Applied Materials, Inc.), or other anti-reflective coating to facilitate the pattering process. Then, in FIG. 3(g), a layer of photoresist 314 is deposited and patterned to define a trench opening 316. As shown in FIG. 3(h), the hardmask layer 312 is removed by etching so as to expose the line dielectric/via fill material 310. Then, using a single etch step, a trench 318 is formed within the line dielectric level and the fill material 310 is removed from via 308, as illustrated in FIG. 3(i).

In order to preserve the integrity of the via corners of the via 308, the sacrificial fill material 310 has an etch selectivity of at least 5 times that of the via dielectric 302, and preferably at least 20 times that of the via dielectric material. Following this etch, the resulting unfilled via 308 and trench 318 are now prepared for standard dual damascene metallization fill and planarization steps.

As will be appreciated, the above described method addresses the problems inherent in conventional, hybrid dual damascene processing by utilizing the sacrificial via fill material to provide a planarized surface following the via formation but before the trench formation. By reducing or eliminating interconnect topography, the puddling of an anti-reflective coating layer (ARC) is prevented. Furthermore, the presence of the sacrificial material preserves the integrity of the via corners during the trench formation, just prior to the removal of the sacrificial material. Similar to single damascene, the separate formation of trench and via also preserves photoresist thickness and can increase device yield, in addition to preserving the corners of the vias during the trench etch. Moreover, the use of the sacrificial fill material as the line level dielectric saves the additional steps of depositing a separate line dielectric, etching out the via sacrificial fill material after the line etch, and also allows the removal of the polish step typically required after the sacrificial via material fill. That is to say, by having the etch chemistry of the sacrificial fill material selective to the via dielectric material, a single etch step may be used to perform both the etch of the trench and the removal of the sacrificial fill. The sacrificial fill material need not be polished flat to the via dielectric, since it will be used for the subsequent line level.

It will also be appreciated that the vias can be filled up with other choices of sacrificial material, depending upon factors such as the type of etching used to remove the material (e.g., a wet etch process versus a dry etch process), or the particular type of semiconductor device being manufactured. For example, the method may be applied to the fabrication of magnetic random access memory (MRAM) devices, in which a magnetic memory element (also referred to as a tunneling magneto-resistive, or TMR device) includes a structure having ferromagnetic layers separated by a non-magnetic layer, and arranged into a magnetic tunnel junction (MTJ). In this application, it may be difficult to employ SiLK_{®} as the choice for the sacrificial fill/line dielectric for MRAM devices, since the curing temperature for SiLK® generally exceeds the temperature which MTJs can bear without getting damaged. Accordingly, other sacrificial materials such as low temperature SiOₓ could be used, in conjunction with a different via dielectric, such as a silicon nitride.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method for forming an interconnect structure in a semiconductor device, the method comprising:
defining a first insulator layer on a substrate;
defining a via in said first insulator layer, thereby exposing a portion of said substrate;
depositing a sacrificial material over said first insulator layer and within said via, said sacrificial material being deposited at a thickness so as to also form a second insulator layer;
defining a metallization line trench in said second insulator layer, said trench aligned over said via; and
removing said sacrificial material from said via, thereby allowing said via and said trench to be filled with a conductive material by dual damascene processing;
wherein the formation of said trench and the removal of said sacrificial material from said via is implemented through a single etching operation.

2. The method of claim 1, wherein said sacrificial material comprises an organic, low-k dielectric material.

3. The method of claim 1, wherein said sacrificial material has an etch selectivity of at least 5 times that of said first insulator layer.

4. The method of claim 1, wherein said sacrificial material has an etch selectivity of at least 20 times that of said first insulator layer.

5. The method of claim 1, wherein said first insulator layer comprises a silicon oxide (SiOₓ) material.

6. A method for forming back end of line (BEOL) interconnect structures in a semiconductor device, the method comprising:
forming a via level dielectric on a lower metallization level;
defining a via in said via level dielectric, thereby exposing a portion of said lower metallization level;
depositing a sacrificial material over said via level dielectric and within said via, said sacrificial material being deposited at a thickness so as to also form a trench level dielectric;
defining an upper metallization line trench in said trench level dielectric, said trench aligned over said via; and
removing said sacrificial material from said via, thereby allowing said via and said trench to be filled with a conductive material by dual damascene processing;
wherein the formation of said trench and the removal of said sacrificial material from said via is implemented through a single etching operation.

7. The method of claim 6, wherein said sacrificial material comprises an organic, low-k dielectric material.

8. The method of claim 6, wherein said sacrificial material has an etch selectivity of at least 5 times that of said first insulator layer.

9. The method of claim 6, wherein said sacrificial material has an etch selectivity of at least 20 times that of said first insulator layer.

10. The method of claim 6, wherein said first insulator layer comprises a silicon oxide (SiOₓ) material.
